(19) United States
(12) Patent Application Publication
(10) Pub. No.: US 2018/0122652 A1
(43) Pub. Date: May 3, 2018

(54) Method of ROI Encapsulation During Axis Conversion of Cross-Sectional TEM Lamellae

(71) Applicant: QUALCOMM Incorporated, San Diego, CA (US)

(72) Inventor: Corey Senowitz, San Diego, CA (US)

(21) Appl. No.: 15/802,268

(22) Filed: Nov. 2, 2017

Related U.S. Application Data
(60) Provisional application No. 62/416,889, filed on Nov. 3, 2016.

(51) Int. Cl. H01L 21/56; H01L 21/3065; H01L 23/544; G01R 31/265; G01R 31/26

(52) U.S. Cl. CPC H01L 21/56; H01L 21/3065; G01R 31/2621; G01R 31/2653; H01L 23/544

(57) ABSTRACT

An axis conversion technique is provided for the milling of lamellae for TEM analysis that includes a sputter deposition to prevent warpage of the axis-converted lamellae.

### CROSS-REFERENCE TO RELATED APPLICATIONS

This application claims the benefit of U.S. Provisional Application No. 62/416,889 filed Nov. 3, 2016.

### TECHNICAL FIELD

This application relates generally to the preparation of lamellae for transmission electron microscopy to analyze semiconductor defects, and more particularly to a method of region-of-interest (ROI) encapsulation during axis conversion of cross-sectional lamellae.

### BACKGROUND

Integrated circuits (ICs) are typically designed using software tools in which designers can combine known components to produce a model for an actual IC. The software can also predict the operation of the modeled device, and the designer can make corrections based on the simulated operation of the modeled circuitry. However, when the IC design is sent to the foundry that produces the actual prototype IC, unexpected defects may occur due to increasingly complicated processing techniques. Such defects are exacerbated as transistor dimensions decrease and advanced processing techniques are utilized. For example, the use of resolution enhancement techniques such as optical proximity correction, phase shift masks, and double patterning lead to variations in lithography that are difficult to accurately model during the design process. Variations in chemical mechanical planarization due to surface density effects and other issues can also contribute to this problem.

When such defects are detected, the circuit designer may send the defective IC to a failure analysis team to identify the defect so that the design may be corrected. Some defects can be observed using non-destructive techniques, e.g., electro-optical techniques such as LVP (Laser Voltage Probing), SDL (Soft Defect Localization), and LADA (Laser Assisted Device Alteration), among others. However, some defects require destructive failure analysis methods in which the IC is milled down to a thin film in order to find the region-of-interest (ROI) for fault detection. One such technique is transmission electron microscopy (TEM), which is commonly used for fault analysis for the latest process nodes (e.g., 7 nm to 20 nm).

To employ TEM, the IC being analyzed is milled into thin samples denoted as “lamellae” (plural). A resulting lamella is then subjected to relatively intense electron bombardment (e.g., in a range of 30 kV to 300 kV). The electrons are imaged after passing through the lamella (hence the use of “transmission” in Transmission Electron Microscopy). The relatively large amounts of power used to excite the electrons in TEM causes the electrons to have short wavelengths. As a result, TEM has much finer resolution than other electron-based microscopy techniques, such as scanning electron microscopy (SEM). The resolution for TEM can thus extend down to the atomic scale, which is very useful for isolating faults in modern process nodes.

Although TEM provides robust resolution, the milling of the lamellae becomes problematic at advanced process nodes. In particular, modern process nodes have moved from the traditional planar transistor architectures to three-dimensional structures such as in a fin-shaped field effect transistor (FinFET). FinFETs differ from planar CMOS (Complementary Metal Oxide Semiconductor) devices in that in a CMOS transistor, a gate controls a channel through only one plane. In such planar processes, the gate may not have good control of the channel, exhibiting leakage currents between the source and drain even when the gate is off. In contrast, the channel in a FinFET is contained within a thin vertical fin with the gate deposited on the two sides and top of the fin so that the channel is controlled from 3 different planes.

Given the three-dimensional structure of a FinFET, the lamella orientation can be either aligned with a longitudinal axis of the gate to form an “y-directed” lamella or aligned with a longitudinal axis of the fin to form an “x-directed lamella.” For example, suppose a FinFET having three fins is determined to be faulty. To isolate the fault, an initial y-directed lamella may be used so that the cross-sectional view of the fins can point to the faulty one. The nature of the fault would then be better determined by converting the y-directed lamella into an x-directed lamella of the faulty fin. But such conversion is hampered in that the initial y-directed lamella is typically quite thin (e.g., less than 40 nm). Although a more robust thickness would be desirable to ease the formation of the x-directed lamella, the presence of the source and drain contacts would compromise the analysis such that the initial y-directed lamella must be relatively thin.

The relatively-thin y-directed lamella would then have structural integrity issues if it were converted into an x-directed lamella without any further modification. It is thus conventional to bolster the y-directed lamella with a electron-beam deposition of a metal such as tungsten (W) prior to the axis conversion of the lamella. But the resulting lamella is then subject to warping due to the residual stress of the tungsten deposition, particularly since the deposition must occur sequentially on each side of the lamella. This warpage prevents the proper formation of the desired x-directed lamella.

Accordingly, there is a need in the art for improved axis conversion techniques for lamellas for TEM-based fault analysis of semiconductor structures.

### SUMMARY

An advantageous axis conversion for semiconductor lamellae used in TEM fault analysis is disclosed that eliminates the warping issues that conventionally occur during the conversion. The conversion begins with the attachment of the semiconductor device to a TEM grid and the subsequent milling of the attached semiconductor device along a first axis to form a first-axis-directed lamella containing a region-of-interest (ROI). One or more markers are then deposited on the first-axis-directed lamella adjacent to the ROI to form a marked first-axis-directed lamella. A strengthening material is then sputtered onto the marked first-axis-directed lamella to cover it with a layer of strengthening material. The first-axis-directed lamella is then detached from the TEM grid and re-mounted in an orthogonal alignment to how it was originally attached to the TEM grid. Guided by the markers, the covered and marked first axis-directed lamella is then milled along a second axis to expose the ROI and form a second-axis-directed lamella, wherein the second axis is substantially orthogonal to the first axis. The sputter deposition of the strengthening layer (e.g., carbon, silicon dioxide, or a metal such as gold, palladium, or chromium) provides rigidity and structural support during the axis conversion of the lamella without the warpage problems from conventional e-beam tungsten deposition techniques. In addition, note that the strengthening material may be deposited using other suitable techniques besides sputtering such as chemical vapor deposition.

These and additional advantages may be better appreciated through the following detailed description.

### BRIEF DESCRIPTION OF THE DRAWINGS

FIG. 1 is a perspective view of a FinFET transistor prior to its cross-sectioning into a lamella.

FIG. 2 is a TEM image of a y-directed lamella from the FinFET transistor of FIG. 1.

FIG. 3 is a scanning electron microscope (SEM) image of an x-directed lamella after deposition of tungsten markers in accordance with an aspect of the disclosure.

FIG. 4 is a TEM image of the lamella of FIG. 3 after its conversion into a y-directed lamella in accordance with an aspect of the disclosure.

FIG. 5 is a flowchart of an method of forming an axis-converted lamella in accordance with an aspect of the disclosure.

These aspects of the disclosure and their advantages are best understood by referring to the detailed description that follows. It should be appreciated that like reference numerals are used to identify like elements illustrated in one or more of the figures.

### DETAILED DESCRIPTION

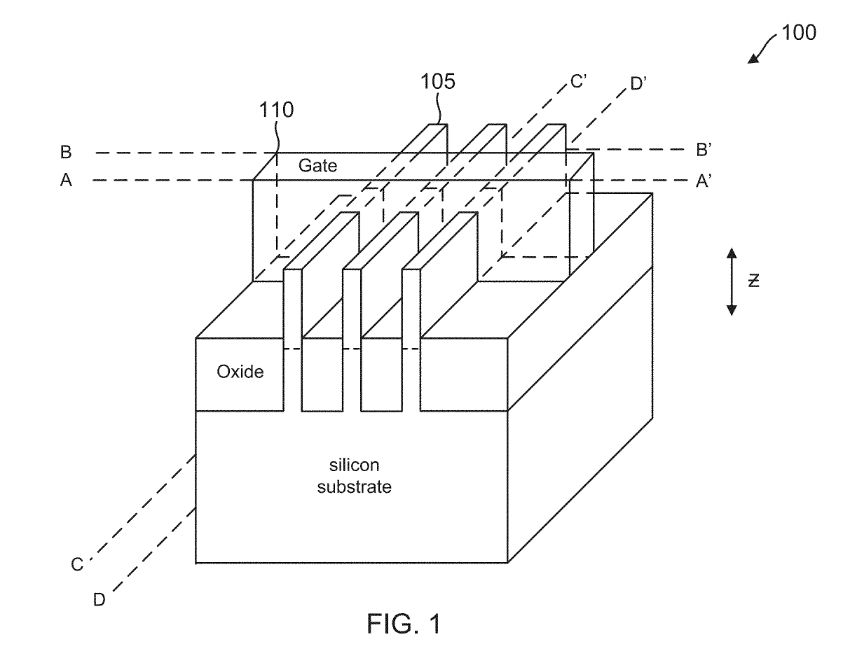

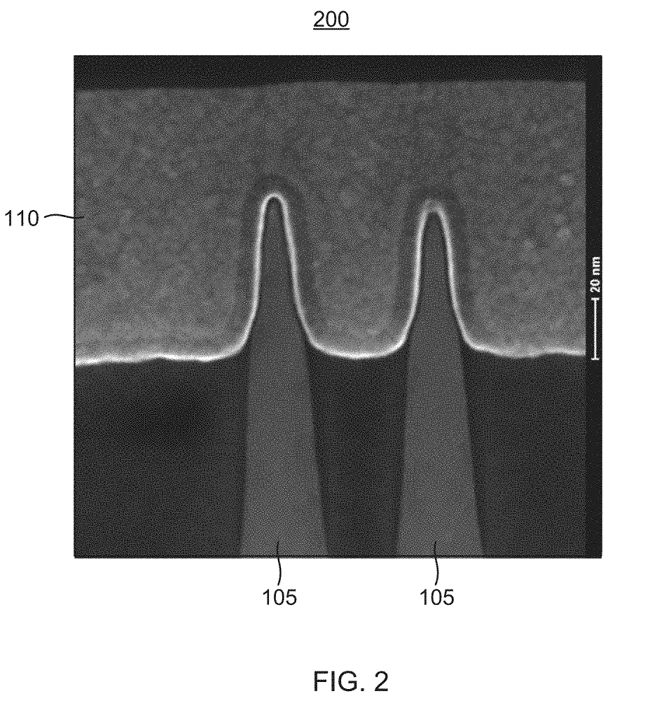

An axis conversion technique for lamellae is provided that avoids the warpage issues that have thwarted prior art axis conversions. The axis conversion may be from a y-directed lamella into an x-directed lamella. Similarly, the axis conversion may be from an x-directed lamella into a y-directed lamella. To better appreciate what is meant by the “y-directed” and “x-directed” lamellae orientations, consider the generic FinFET transistor 100 shown in FIG. 1. For illustration clarity, the source and drain contacts as well as the gate spacers are not shown in FIG. 1. A gate 110 overlaps three fins 105 that are separated by oxide regions covering a silicon substrate. An analogous topology would be used in a silicon-on-insulator architecture. Prior to the lamella formation, the silicon substrate may be thinned such as through a chemical-mechanical planarization step. To form a y-directed lamella, FinFET 100 is cross-sectioned along lines A:A′ and B:B′ at the edges of gate 110. The milling of FinFET 100 may be performed using a dual beam focused ion beam (FIB) process as known in the TEM arts. A portion of a TEM image 200 of a resulting y-directed lamella is shown in FIG. 2. In image 200, only two fins 105 are shown in cross-section and surrounded by gate 110. Referring back to FIG. 1, it will be appreciated that image 200 would result if FinFET 100 were cross-sectioned in the z direction along either of line A:A′ FIG. 2 or B:B′. Note that other types of three-dimensional devices such as nanowire devices may be analyzed using such a dual-axis milling technique.

Analysis of image 200 may show that a particular fin 105 is defective such that an x-directed axis conversion of the y-directed lamella parallel to a longitudinal axis of the defective fin would be desirable. But note that the y-directed lamella must be quite thin such as a thickness no more than the approximate width of gate 110 (FIG. 1) to prevent cross-sectioning into the source and drain contacts. The axis conversion of such a thin lamella is problematic without a conventional electron-beam tungsten deposition to provide structural rigidity but such a deposition often results in severe warpage of the lamella, particularly due to the sequential nature of the e-beam deposition with regard to covering one side and then another of the lamella. To prevent this warpage, the lamella is instead subjected to a sputter deposition of a strengthening material to cover the lamella with a layer of the strengthening material. To limit the danger of warpage, the strengthening material may comprise a relatively-low molecular weight material such as carbon or silicon dioxide. However, metals may also be used as the strengthening material in the sputter deposition. The following discussion will thus be directed to a carbon deposition embodiment without loss of generality.

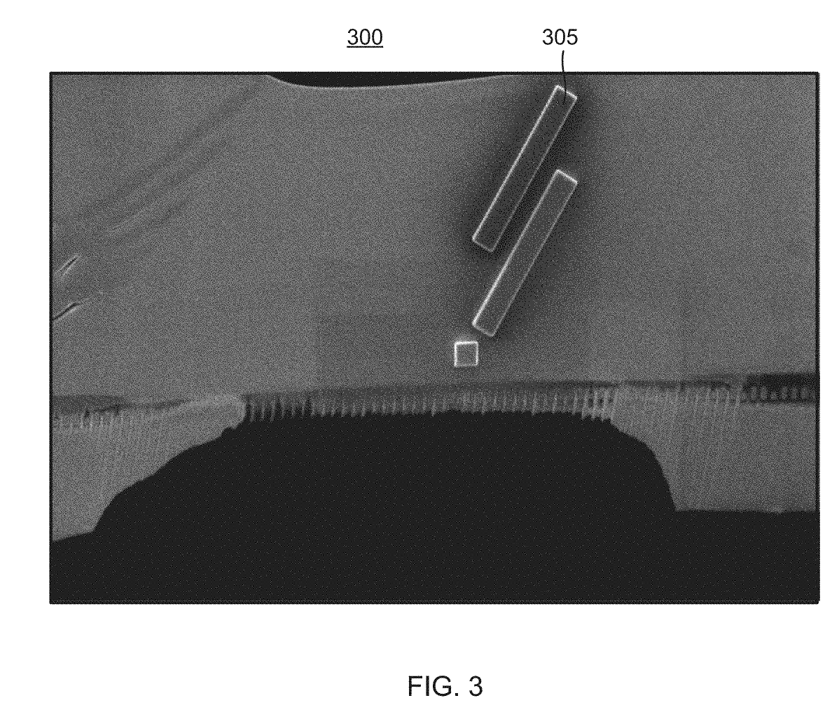

The carbon deposition covers all the surfaces of the lamella such that it can be problematic to appropriately mill the lamella during its axis conversion into a x-directed lamella. To provide a landmark for the axis conversion, a marker of a suitable material is deposited adjacent to the region-of-interest (such as the defective fin) such as through an electron beam or an ion beam deposition. To distinguish the marker from the strengthening material, it is preferable that the marker be a different material, for example a metal such as tungsten or platinum in the case of a carbon sputtering. The marked-lamella from such a deposition that is then sputtered with carbon. An example SEM image 300 of a x-directed lamella with several tungsten markers 305 prior to the carbon deposition is shown in FIG. 3. Markers 305 are placed relatively high up on the lamella in the region of the silicon substrate. Due to the inverted wedge shaping of the lamella as resulting from the FIB milling, the lamella is relatively thick in the silicon substrate portion such that there is little susceptibility to warpage due to the tungsten deposition. The subsequent carbon deposition may be performed in a carbon coater sputter tool. The resulting carbon layer thickness may vary but an example thickness would be approximately 100 nm.

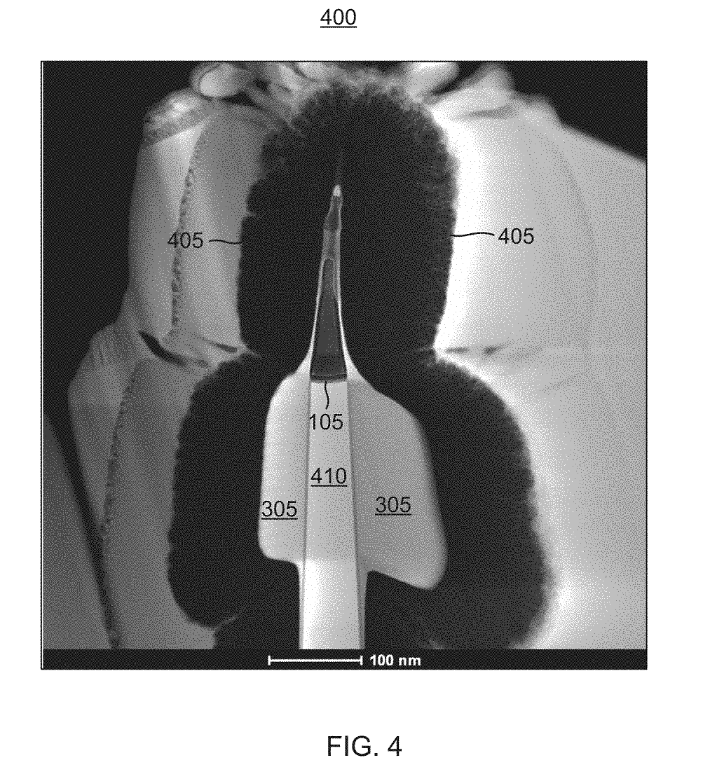

A TEM image 400 after an axis conversion of the x-directed lamella of FIG. 3 into a y-directed lamella 410 is shown in FIG. 4A. A fin 105 is seen in cross-section at the apex of y-directed lamella 410. A marker 305 was positioned at the base of fin 105 to guide the milling of y-directed lamella 410. Carbon layer 405 covers the “x-faces” of y-directed lamella 410. Referring again to FIG. 1, one x-face is defined by line C:C′ whereas another is defined by line D:D′. What is seen in FIG. 4 is the “y-face” of y-directed lamella 410, which is defined by either line A:A′ or line B:B′. Carbon layers 405 are quite advantageous in that the y-directed lamella is quite small due to the axis conversion. As seen in FIG. 1, the x and y faces for the y-directed lamella of the ROI after axis conversion from an x-directed lamella would be defined by the intersection of lines A:A′ and B:B′ with lines C:C′ and D:D′. Note that the x and y faces would generally be aligned so as to isolate a single fin. Despite this small size, carbon layers 405 allow the analyst to manipulate the lamella without the warpage caused by conventional tungsten deposition. Note further that the carbon sputtering causes no damage to the lamella due to ion implantation. In contrast, the conventional ion beam deposition of tungsten onto the lamella prior to the axis conversion may cause considerable ion implantation damage. The resulting damage makes the fault analysis much more challenging. In contrast, the sputter deposition of the strengthening material such as carbon as disclosed herein prior to the axis conversion does not result in ion implantation damage.

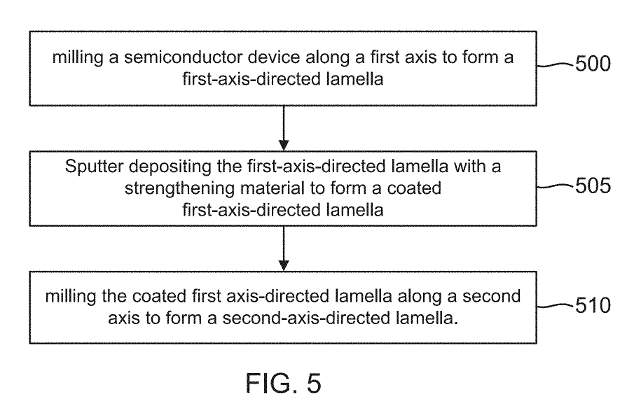

A method of forming an axis-converted lamella will now be discussed with regard to the flowchart of FIG. 5. This method is generic to the conversion of an x-directed lamella into a y-directed lamella or to the conversion of a y-directed lamella into an x-directed lamella. The method includes an act 500 of milling a semiconductor device along a first axis to form a first-axis-directed lamella. The milling of the y-directed lamella of FIG. 1 or the x-directed lamella of FIG. 3 is an example of act 500. The method also includes an act 505 of sputter depositing the first-axis-directed lamella with a strengthening material to form a coated first-axis-directed lamella such as discussed above with regard to sputtering the initial lamella prior to axis conversion with carbon. Finally, the method includes an act 510 of milling the coated first axis-directed lamella along a second axis to form a second-axis-directed lamella. The conversion into the y-directed lamella of FIG. 4 is an example of act 510. As discussed earlier, the milling of a lamella in either axis direction requires first that the lamella be attached to a TEM grid. The milling in a second axis direction such as performed in act 510 would thus involve the detachment of the lamella from the TEM grid so as to be re-attached to the TEM grid with the proper alignment for the second axis-directed milling.

As those of some skill in this art will by now appreciate and depending on the particular application at hand, many modifications, substitutions and variations can be made in and to the materials, apparatus, configurations and methods of use of the devices of the present disclosure without departing from the scope thereof. For example, the semiconductor device being milled need not comprise a FinFET but instead may comprise a nanowire device or a planar CMOS transistor. In light of this, the scope of the present disclosure should not be limited to that of the particular embodiments illustrated and described herein, as they are merely by way of some examples thereof, but rather, should be fully commensurate with that of the claims appended hereafter and their functional equivalents.

What is claimed is:

1. A method, comprising:
milling a semiconductor device along a first axis to form a first-axis-directed lamella;
depositing the first-axis-directed lamella with a strengthening material to form a coated first-axis-directed lamella;
milling the coated first axis-directed lamella along a second axis to form a second-axis-directed lamella.

2. The method of claim 1, wherein depositing the strengthening material comprises sputter depositing the strengthening material, the method further comprising:
imaging the second axis-directed lamella with transmission electron microscopy to detect a fault in the semiconductor device.

3. The method of claim 1, wherein the semiconductor device is a fin-shaped field effect transistor (FinFET), and wherein milling the semiconductor device along the first axis comprises milling parallel to a longitudinal axis of a gate such that the first-axis-directed lamella is a y-directed lamella, and wherein the sputter depositing comprises a sputter depositing with carbon.

4. The method of claim 3, wherein milling the coated first-axis-directed lamella comprises milling parallel to a longitudinal axis of a fin such that the second-axis-directed lamella is an x-directed lamella.

5. The method of claim 1, wherein the semiconductor device is a fin-shaped field effect transistor (FinFET), and wherein milling the semiconductor device along the first axis comprises milling parallel to a longitudinal axis of a fin such that the first-axis-directed lamella is an x-directed lamella.

6. The method of claim 5, wherein milling the coated first-axis-directed lamella comprises milling parallel to a longitudinal axis of a gate such that the second-axis-directed lamella is a y-directed lamella.

7. The method of claim 1, further comprising marking the first-axis-directed lamella with a marker adjacent a region-of-interest (ROI) prior to the coating.

8. The method of claim 7, wherein marking the first-axis-directed lamella with a metallic marker comprises a tungsten electron beam depositing of at least one tungsten marker.

9. The method of claim 1, wherein coating the first-axis-directed lamella comprises sputtering the first-axis-directed lamella with a metal.

10. An axis-converted lamella of a semiconductor device, comprising:
a first-axis-directed face along a region of interest (ROI) of the semiconductor device;
a pair of second-axis-directed faces substantially orthogonal to the first-axis-directed face; and
a strengthening material layer covering only the pair of second-axis-directed faces.

11. The axis-converted lamella of claim 10, wherein the semiconductor device is a fin-shaped field effect transistor (FinFET), and wherein the first-axis-directed face is aligned parallel to a longitudinal axis of a fin, and wherein the pair of second-axis-directed faces are aligned parallel to a longitudinal axis of a gate.

12. The axis-converted lamella of claim 10, wherein the strengthening material is a sputter-deposited strengthening material and the semiconductor device is a fin-shaped field effect transistor (FinFET), and wherein the first-axis-directed face is aligned parallel to a longitudinal axis of a gate, and wherein the pair of second-axis-directed faces are aligned parallel to a longitudinal axis of a fin.

13. The axis-converted lamella of claim 10, wherein the semiconductor device is a nanowire device.

14. The axis-converted lamella of claim 10, wherein the semiconductor device is a planar CMOS transistor.

15. An axis-converted lamella of a fin-shaped field effect transistor (FinFET), comprising;
a portion of a fin, wherein the portion has a first pair of faces that are parallel to a longitudinal axis of a gate associated with the fin and has a second pair of faces that are parallel to a longitudinal axis of the fin; and
a sputter-deposited strengthening material covering the first pair of faces.

16. The axis-converted lamella of claim 15, wherein the strengthening material comprises sputter-deposited carbon.

17. The axis-converted lamella of claim 15, further comprising:
a portion of a substrate at a base of the portion of the fin; and
an ion-beam deposited marker on the portion of the substrate.

18. An axis-converted lamella of a fin-shaped field effect transistor (FinFET), comprising;
a portion of a fin, wherein the portion has a first pair of faces that are parallel to a longitudinal axis of a gate associated with the fin and has a second pair of faces that are parallel to a longitudinal axis of the fin; and
a sputter-deposited strengthening material covering the second pair of faces.

19. The axis-converted lamella of claim 18, wherein the sputter-deposited strengthening material comprises sputter-deposited carbon.

20. The axis-converted lamella of claim 18, further comprising:
a portion of a substrate at a base of the portion of the fin; and
an electron-beam deposited marker on the portion of the substrate.
